(19) United States
(12) Patent Application Publication
(10) Pub. No.: US 2025/0306578 A1
(43) Pub. Date: Oct. 2, 2025

(54) SIMULATOR APPARATUS, SUBSTRATE PROCESSING APPARATUS, SIMULATION METHOD, METHOD OF MANUFACTURING SEMICONDUCTOR DEVICE AND NON-TRANSITORY COMPUTER-READABLE RECORDING MEDIUM

(71) Applicant: KOKUSAI ELECTRIC CORPORATION, Tokyo (JP)

(72) Inventors: Tatsuki HOSHIBA, Toyama-shi (JP); Mitsuru FUKUDA, Toyama-shi (JP)

(73) Assignee: KOKUSAI ELECTRIC CORPORATION, Tokyo (JP)

(21) Appl. No.: 19/083,122

(22) Filed: Mar. 18, 2025

(30) Foreign Application Priority Data
Mar. 27, 2024 (JP) 2024-052454

(51) Int. Cl. G05B 19/418

(52) U.S. Cl. CPC G05B 19/41885; G05B 2219/45031

(57) ABSTRACT

It is possible to reduce a time for editing a recipe by simulating a processing operation for a substrate based on an edited recipe without using a substrate processing apparatus. There is provided a technique that includes: a virtual apparatus memory storing a recipe and an apparatus control program, wherein the recipe includes steps defining process conditions and a process time, and the apparatus control program controls substrate processing; a start-up operator selecting an execution speed of the apparatus control program and a transfer operation mode of a substrate transfer structure selected from a normal transfer operation and a transfer skip operation; a virtual controller capable of starting the apparatus control program based on the execution speed and the transfer operation mode and controlling a virtual processing of the substrate based on the recipe stored in the virtual apparatus memory.

### CROSS-REFERENCE TO RELATED PATENT APPLICATION

This non-provisional U.S. patent application is based on and claims priority under 35 U.S.C. § 119 of Japanese Patent Application No. 2024-052454, filed on Mar. 27, 2024, in the Japanese Patent Office, the entire contents of which are hereby incorporated by reference.

### BACKGROUND

### 1. Field

The present disclosure relates to a simulator apparatus, a substrate processing apparatus, a simulation method, a method of manufacturing a semiconductor device and a non-transitory computer-readable recording medium.

### 2. Related Art

According to some related arts, in a substrate processing apparatus, a recipe capable of setting process conditions for processing a substrate at each step may be edited, or a parameter for executing the recipe may be edited. When the recipe or the parameter is edited, the substrate may be processed using the edited recipe or the edited parameter.

When processing the substrate using the edited recipe or the edited parameter, in the substrate processing apparatus, a processing operation for the substrate may be checked in advance using the edited recipe. In such a case, when a processing result of the substrate does not match an expected result, the recipe may be repeatedly modified and checked. This may waste time by using the substrate processing apparatus exclusively for such works and editing the recipe.

### SUMMARY

According to the present disclosure, there is provided a technique capable of reducing a time for editing a recipe by simulating a processing operation for a substrate based on an edited recipe without using a substrate processing apparatus.

According to an embodiment of the present disclosure, there is provided a technique that includes: a virtual apparatus memory configured to store a recipe and an apparatus control program, wherein the recipe is constituted by a plurality of steps defining process conditions and a process time for a substrate, and the apparatus control program is configured to control a processing of the substrate performed by a substrate processing apparatus using the recipe; a start-up operator configured to select an execution speed of the apparatus control program and a transfer operation mode of a transfer structure transferring the substrate, wherein the transfer operation mode is selected from a normal transfer operation and a transfer skip operation; a virtual controller configured to be capable of starting the apparatus control program based on the execution speed and the transfer operation mode of the transfer structure, and capable of controlling a virtual processing of the substrate based on the recipe stored in the virtual apparatus memory.

### BRIEF DESCRIPTION OF THE DRAWINGS

FIG. 1 is a block diagram schematically illustrating an exemplary configuration of a simulator according to one or more embodiments of the present disclosure.

FIG. 2 is a diagram schematically illustrating an example of apparatus information according to the embodiments of the present disclosure.

FIG. 3 is a diagram schematically illustrating an exemplary perspective view of a substrate processing apparatus according to the embodiments of the present disclosure.

FIG. 4 is a diagram schematically illustrating a cross-section of the substrate processing apparatus according to the embodiments of the present disclosure, when viewed from side thereof.

FIG. 5 is a block diagram schematically illustrating an exemplary functional configuration of a control apparatus of the substrate processing apparatus according to the embodiments of the present disclosure.

FIG. 6A is a diagram schematically illustrating an example of screen transitions on a display manipulator associated with a start-up process of the simulator according to the embodiments of the present disclosure.

FIG. 6B is a diagram schematically illustrating another example of the screen transitions on the display manipulator associated with the start-up process of the simulator according to the embodiments of the present disclosure.

FIG. 6C is a diagram schematically illustrating still another example of the screen transitions on the display manipulator associated with the start-up process of the simulator according to the embodiments of the present disclosure.

FIG. 6D is a diagram schematically illustrating still another example of the screen transitions on the display manipulator associated with the start-up process of the simulator according to the embodiments of the present disclosure.

FIG. 7 is a flow chart schematically illustrating an example of the start-up process according to the embodiments of the present disclosure.

### DETAILED DESCRIPTION

### Embodiments of Present Disclosure

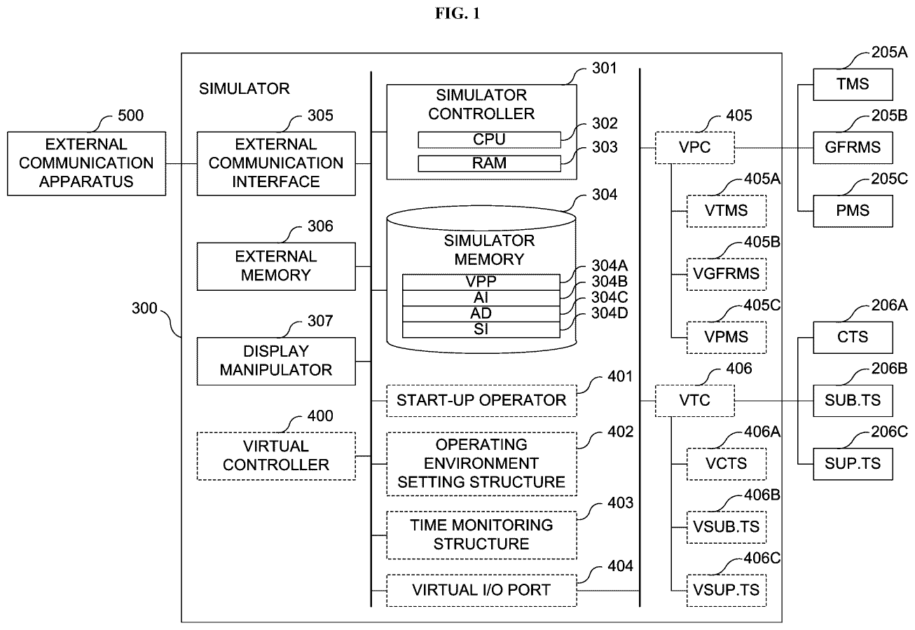

Hereinafter, one or more embodiments (also simply referred to as “embodiments”) according to the technique of the present disclosure will be described mainly with reference to FIGS. 1 to 7. Further, the drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match. In addition, the technique of the present disclosure is not limited to the embodiments described below. That is, the technique of the present disclosure may be modified in various ways without departing from the scope thereof.

In addition, in the following description, the term “worker” refers to a person who uses a simulator or a substrate processing apparatus or a person who processes a substrate using the substrate processing apparatus. In addition, the substrate processing apparatus may also be simply referred to as an “apparatus”.

### Simulator

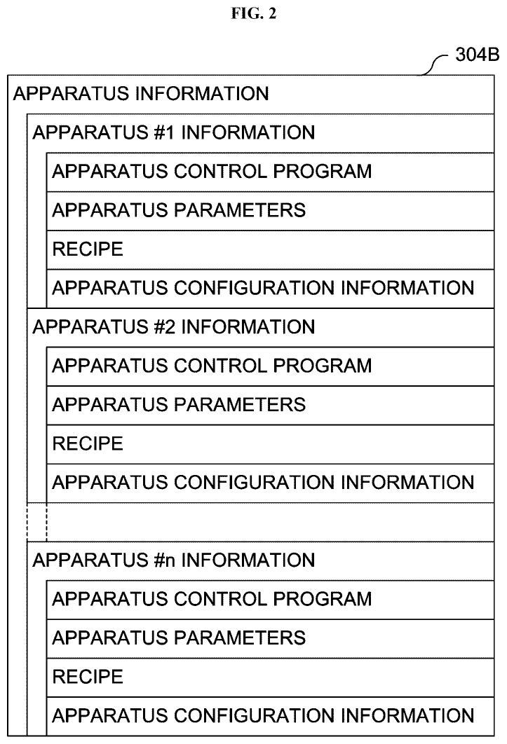

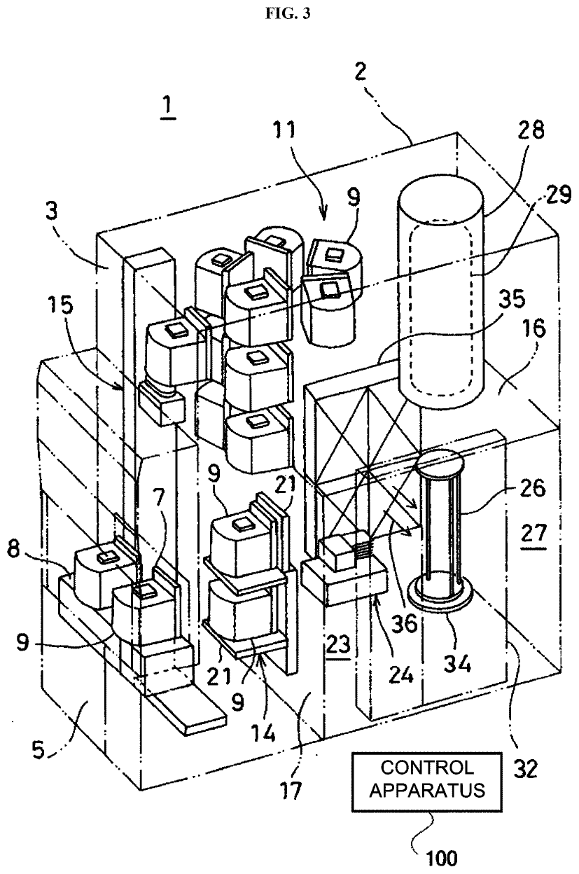

First, an overview of a simulator 300 serving as a simulator apparatus according to the present embodiments will be described with reference to FIGS. 1 and 2. FIG. 1 is a block diagram schematically illustrating an exemplary configuration of the simulator 300 according to the present embodiments. The simulator 300 can execute a simulation for steps of a substrate processing. The simulation serves as a virtual processing for a plurality of apparatuses including a substrate processing apparatus 1 (see FIGS. 3 to 5) described later. In addition, in FIG. 1, blocks shown with solid lines indicate hardware configurations, and blocks shown with dashed lines indicate functional configurations.

### Hardware Configuration of Simulator

As shown in FIG. 1, the simulator 300 includes a simulator controller 301, a simulator memory 304 serving as a virtual apparatus memory, an external communication interface 305, an external memory 306 and a display manipulator 307 serving as a virtual apparatus display manipulator.

The simulator controller 301 includes a CPU (Central Processing Unit) 302 and a RAM (Random Access Memory) 303.

The CPU 302 is a central processing unit configured to execute various programs and to control components constituting the simulator 300. The RAM 303 serves as a work area, and is configured to temporarily store the program or data. The simulator memory 304 is configured to store various programs and various data. In other words, according to the present embodiments, the CPU 302 of the simulator 300 functions as the simulator 300 by writing a program stored in the simulator memory 304 to the RAM 303, and executing the program.

As the simulator memory 304, for example, a component such as a hard disk drive (HDD), a solid state drive (SSD) and a flash memory may be used. According to the present embodiments, in the simulator memory 304, a virtual processing program (“VPP” in FIG. 1) 304A, apparatus information (“AI” in FIG. 1) 304B, apparatus data (“AD” in FIG. 1) 304C and selection information (“SI” in FIG. 1) 304D may be stored.

The virtual processing program 304A is a program for executing functions of the simulator 300, including a start-up process described later. For example, the virtual processing program 304A may be installed in the simulator 300 in advance. Alternatively, the virtual processing program 304A may be embodied by recording a program related thereto on a non-volatile recording medium (or distributing the program related thereto via a network) and installing the program related thereto appropriately in the simulator 300. For example, as the non-volatile recording medium, a component such as a CD-ROM, a magneto-optical disk, a hard disk drive (HDD), a DVD-ROM, a flash memory, a memory card and a USB memory may be used.

FIG. 2 is a diagram schematically illustrating an example of the apparatus information 304B according to the present embodiments.

As shown in FIG. 2, in the apparatus information 304B, information about the plurality of apparatuses may be stored. For example, in the apparatus information 304B, information about a first apparatus (also referred to as an “apparatus #1”) to an nth apparatus (also referred to as an “apparatus #n”) may be stored. In apparatus #1 information (which is information about the apparatus #1), an apparatus control program, apparatus parameters, a recipe and apparatus configuration information provided by the apparatus #1 may be stored. In apparatus #2 information (which is information about the apparatus #2), an apparatus control program, apparatus parameters, a recipe and apparatus configuration information provided by the apparatus #2 may be stored. The same also applies to apparatus #n information below, where n is an integer of 3 or more. In addition, in the apparatus information 304B, information about at least one of the apparatuses mentioned above may be stored.

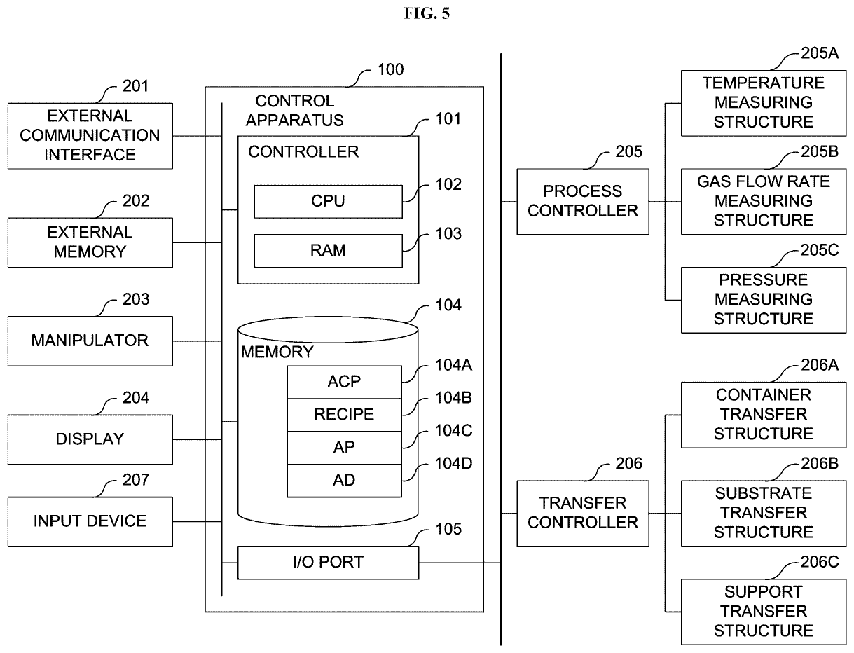

The apparatus control program is a program installed in each apparatus, and various screens to be displayed on a display of each apparatus can be displayed on the display manipulator 307 described later. For example, the apparatus control program is a program similar to an apparatus control program (“ACP” in FIG. 5) 104A described later. Therefore, according to the simulator 300 of the present embodiments, it is possible to edit the recipe in the same (substantially the same) way as each apparatus, and it is also possible to simulate the substrate processing using the recipe which is edited. In addition, the simulator 300 is also provided with the external memory 306 described later. Therefore, it is possible to deploy the edited recipe to each apparatus via the external memory 306, or it is also possible to copy the recipe from each apparatus and store the recipe in the simulator memory 304. Therefore, according to the simulator 300 of the present embodiments, by making it possible to edit the recipe on the simulator 300, it is possible to immediately check an operation of the edited recipe, and it is also possible to contribute to reducing a work of copying and using an externally edited recipe.

The apparatus parameters indicate parameters of equipment installed in each apparatus. For example, the apparatus parameters are parameters similar to apparatus parameters (“AP” in FIG. 5) 104C described later. For example, the apparatus parameters are parameters storing hardware configurations of each apparatus (for example, the number of the hardware configurations, the number of sheets, locations and the like) and process conditions (for example, numerical ranges). In addition, in the apparatus parameters, connection destination information serving as connection conditions for a real measuring structure (actual measuring structure) or a virtual measuring structure described later may be stored. In the present embodiments, the term “real structure” may refer to a real equipment (a real apparatus and the like) which is actually operated, and the term “virtual” is used to refer to an equipment, an apparatus and the like which exist on data and is operated in the simulation.

The recipe is information that defines the process conditions and process procedures used to process the substrate in each apparatus. For example, the recipe is similar to a recipe 104B (see FIG. 5) described later.

The apparatus configuration information indicates information for operating each apparatus on the simulator 300. For example, the apparatus configuration information is information indicating configurations of folders used by each apparatus, or data configuration of the recipe or the apparatus control program deployed in each folder.

In the apparatus data 304C in FIG. 1, measurement data acquired from each measuring structure may be stored. Specifically, in the apparatus data 304C, data acquired from a virtual measuring structure controller described later may be stored.

In the selection information 304D, information about environmental settings of a start-up environment of the simulator 300 may be stored. For example, in the selection information 304D, information selected by a start-up operator 401 described later may be stored.

The external communication interface 305 is configured to communicate with an external communication apparatus 500. The external communication interface 305 is connected to a network such as the Internet, a LAN (Local Area Network) and a WAN (Wide Area Network), and is configured to be capable of communicating with external apparatuses via the network. For example, the simulator 300 is connected to a host computer (which serve as the external communication apparatus 500) capable of managing each apparatuses via the external communication interface 305. Therefore, according to the simulator 300 of the present embodiments, by being provided with the external communication interface 305, it is possible to check a communication operation with the external communication apparatus 500 without waiting for the apparatus to be assembled, etc., and it is also possible to reduce an amount of a work to start up the apparatus.

In addition, the external memory 306 is connected to the simulator 300. For example, a USB (Universal Serial Bus) memory (which is an example of the recording medium) can be inserted and removed with respect to the external memory 306.

The display manipulator 307 is configured to display various operation screens for operating the simulator 300. For example, the display manipulator 307 is configured as a touch panel. In addition, for example, the display manipulator 307 may be constituted by a liquid crystal display panel and an input device such as a keyboard and a mouse.

### Functional Configuration of Simulator

By the CPU 302 executing the virtual processing program 304A, the simulator 300 according to the present embodiments functions as a virtual controller 400, the start-up operator 401, an operating environment setting structure 402, a time monitoring structure 403, a virtual I/O (input/output) port 404, a virtual process controller (“VPC” in FIG. 1) 405 connected to measuring structures of a process system (also referred to as “process system measuring structures”), and a virtual transfer controller (“VTC” in FIG. 1) 406 connected to measuring structures of a transfer system (also referred to as “transfer system measuring structures”). The virtual process controller 405 and the virtual transfer controller 406 may also be collectively or individually referred to as the “virtual measuring structure controller”. The simulator 300 also functions as a virtual temperature measuring structure (“VTMS” in FIG. 1) 405A, a virtual gas flow rate measuring structure (“VGFRMS” in FIG. 1) 405B, a virtual pressure measuring structure (“VPMS” in FIG. 1) 405C and the like, which are the measuring structures of the process system connected to the virtual process controller 405 in the simulation. The simulator 300 also functions as a virtual container transfer structure (“VCTS” in FIG. 1) 406A, a virtual substrate transfer structure (“VSUB.TS” in FIG. 1) 406B, a virtual support transfer structure (“VSUP.TS” in FIG. 1) 406C and the like, which are transfer structures connected to the virtual transfer controller 406 in the simulation. The virtual temperature measuring structure 405A, the virtual gas flow rate measuring structure 405B, the virtual pressure measuring structure 405C, the virtual container transfer structure 406A, the virtual substrate transfer structure 406B and the virtual support transfer structure 406C may also be collectively or individually referred to as the “virtual measuring structure”.

The virtual controller 400 retains a function to execute the simulation for the steps of the substrate processing. For example, the virtual controller 400 configures the simulator based on an appropriate apparatus selected by the start-up operator 401 described later, and the apparatus parameters and the apparatus configuration information stored in the apparatus information 304B. Then, the virtual controller 400 controls the simulation for the steps of the substrate processing based on an execution speed, a transfer operation mode selected by the start-up operator 401, and the control apparatus program and the recipe stored in the apparatus information 304B. For example, the virtual controller 400 retains a function to simulate functions of a control apparatus 100 described later.

The start-up operator 401 retains a function of setting the start-up environment of the simulator 300. Specifically, according to the present embodiments, the start-up operator 401 selects the apparatus to be started, selects the execution speed, and selects the transfer operation mode serving as a transfer operation of the transfer structure. For example, the apparatus to be started is selected from the plurality of apparatuses stored in the apparatus information 304B. For example, the execution speed is selected from a plurality of execution speeds including a real speed (actual speed), a double speed and a quadruple speed. In addition, the execution speed may be a speed that slows down the execution speed, such as a ½ speed and a ⅓ speed. For example, the transfer operation mode is selected from a plurality of transfer operation modes including a normal transfer operation and a transfer skip operation. The transfer skip operation is a mode in which a predetermined transfer step is skipped. For example, when the transfer skip operation is selected, the simulator 300 skips the transfer step of the virtual container transfer structure 406A described later and executes the simulation. The transfer skip operation may be performed by skipping at least one among transfer steps of the transfer structure such as the virtual container transfer structure 406A, the virtual substrate transfer structure 406B and the virtual support transfer structure 406C, which will be described later.

That is, according to the present embodiments, the simulator 300 is capable of selecting and starting a specified apparatus from the plurality of apparatuses. Therefore, according to the simulator 300 of the present embodiments, the worker can check the operation of various apparatuses by selecting the specified apparatus from the plurality of apparatuses with a single simulator (that is, the simulator 300).

In addition, according to the present embodiments, the simulator 300 can select the execution speed from the real speed, the double speed and the quadruple speed, and the simulator controller 301 controls the apparatus control program in accordance with the execution speed selected as described above. Therefore, according to the simulator 300 of the present embodiments, it is possible to perform a simulation operation in a shorter time by changing the execution speed, and it is also possible to reduce an amount of a work such as the work to start up the apparatus.

In addition, according to the present embodiments, the simulator 300 can start up the apparatus by selecting the transfer operation mode, and the simulator controller 301 controls the apparatus control program in accordance with the transfer operation mode selected as described above. Therefore, according to the simulator 300 of the present embodiments, when the transfer skip operation is selected as the transfer operation, it is possible to skip the operation of the transfer system. Thereby, it is possible to check operations (steps) of a substrate processing operation (that is, a processing operation for a substrate) in a shorter time.

In addition, the start-up operator 401 cannot specify a transfer skip operation when a connection destination (which is to be connected to the virtual transfer controller 406 described later) is a real measuring structure. For example, the start-up operator 401 inactivates a designation of the transfer operation mode on a display screen by making it invisible or unelectable. In other words, when the destination connected to the virtual transfer controller 406 is the real apparatus, the normal transfer operation alone can be checked to check the operation of the real apparatus. According to the simulator 300 of the present embodiments, it is possible to reduce an influence on the transfer operation when operating the real apparatus.

The operating environment setting structure 402 is configured to deploy the configuration of the apparatus selected by the start-up operator 401 and various information for operating the apparatus. Specifically, the operating environment setting structure 402 acquires the apparatus configuration information for the apparatus from the apparatus information 304B, generates a folder from the apparatus configuration information and deploys various information for operating the apparatus such that the apparatus selected as described above can be operated. In other words, even when configurations of the plurality of apparatuses are different, by automatically deploying the configuration of the apparatus after selecting the apparatus as described above, the simulator 300 can simulate the apparatus without manually setting the configuration that matches the apparatus by the worker. Therefore, according to the simulator 300 of the present embodiments, it is possible to contribute to shortening a set-up time of the simulator 300.

In addition, the operating environment setting structure 402 acquires the apparatus parameters of the apparatus (which is selected) from the apparatus information 304B and deploys the apparatus parameters in the folder generated as described above. In other words, since the operating environment setting structure 402 deploys the apparatus parameters defining the configuration of the apparatus which is selected, the worker can build an operating environment for the simulator 300 without manually setting the configuration of the real measuring structure or the virtual measuring structure. Therefore, according to the simulator 300 of the present embodiments, it is possible to contribute to shortening an environment set-up time of the simulator 300.

The time monitoring structure 403 switches a time reporting period in accordance with the execution speed selected by the start-up operator 401. For example, the time monitoring structure 403 reports the time in 1 second increments when the execution speed is the real speed, in 0.5 second increments when the execution speed is the double speed, and in 0.25 second increments when the execution speed is the quadruple speed. Therefore, according to the simulator 300 of the present embodiments, since the time monitoring structure 403 monitors the time of the simulator 300, it is possible to centrally manage the time monitoring for various configurations in accordance with the execution speed specified (or selected) as described above.

For example, the virtual I/O port 404 retains a function of simulating connections for transmitting and receiving each piece of data, and downloading and uploading each file. In other words, the simulator 300 connects to each of the virtual process controller 405 and the virtual transfer controller 406 via the virtual I/O port 404 in the simulation. For example, the virtual I/O port 404 retains a function of simulating a function of an I/O port 105 (see FIG. 5) described later.

In addition, the virtual I/O port 404 performs a connection operation and a control operation in accordance with each connection destination information defined in the apparatus parameters. For example, as the connection destination information, an IP address may be used. When a local IP address (for example, 127.0.0.1) is specified as the IP address, it is determined that a target apparatus is the virtual measuring structure, and when a normal IP address (for example, 192.168.0.3) is specified as the IP address, it is determined that the real measuring structure is connected as the target apparatus. Therefore, the apparatus control program and the apparatus parameters installed in the apparatus can be used directly in the simulator 300.

The virtual process controller 405 retains a function similar to that of a process controller 205 (see FIG. 5) described later. In addition, the virtual process controller 405 retains a function of connecting, in the simulation, to the virtual measuring structure, that is, the virtual temperature measuring structure 405A, the virtual gas flow rate measuring structure 405B and the virtual pressure measuring structure 405C. Each of the virtual temperature measuring structure 405A, the virtual gas flow rate measuring structure 405B and the virtual pressure measuring structure 405C constitutes the measuring structure in the simulation, and is capable of sending and receiving measurement data to and from the virtual process controller 405, for example.

A heating structure constituted mainly by a heater and a temperature sensor is connected to the virtual temperature measuring structure 405A in the simulation. For example, in the simulation, the virtual temperature measuring structure 405A is configured to measure a temperature of the heater in a process furnace, a temperature (inner temperature) of a process chamber and a temperature of the substrate. For example, the virtual temperature measuring structure 405A retains a function of simulating a function of a temperature measuring structure 205A (see FIG. 5) described later.

An MFC (Mass Flow Controller) serving as a gas flow rate controller is connected to the virtual gas flow rate measuring structure 405B in the simulation. For example, the virtual gas flow rate measuring structure 405B is configured to measure a flow rate of a gas supplied into the process chamber in the simulation. For example, the virtual gas flow rate measuring structure 405B retains a function of simulating a function of a gas flow rate measuring structure 205B (see FIG. 5) described later.

A gas exhaust structure constituted mainly by a pressure sensor and an APC (automatic pressure control) valve serving as a pressure valve is connected to the virtual pressure measuring structure 405C in the simulation. For example, the virtual pressure measuring structure 405C is configured to measure a pressure (inner pressure) of the process chamber in the simulation. For example, the virtual pressure measuring structure 405C retains a function of simulating a function of a pressure measuring structure 205C (see FIG. 5) described later.

In addition, the virtual process controller 405 is connected to the temperature measuring structure 205A, the gas flow rate measuring structure 205B and the pressure measuring structure 205C, which serve as the measuring structures of the process system described later. The temperature measuring structure 205A, the gas flow rate measuring structure 205B and the pressure measuring structure 205C may be collectively or individually referred to as the “real measuring structure”.

The virtual transfer controller 406 retains a function similar to that of a transfer controller 206 (see FIG. 5) described later. In addition, the virtual transfer controller 406 retains a function of connecting, in the simulation, to the virtual transfer structure, that is, the virtual container transfer structure 406A, the virtual substrate transfer structure 406B and the virtual support transfer structure 406C. Each of the virtual container transfer structure 406A, the virtual substrate transfer structure 406B and the virtual support transfer structure 406C constitutes the measuring structure in the simulation, and is capable of sending and receiving measurement data to and from the virtual transfer controller 406, for example.

The virtual container transfer structure 406A is constituted by components in the simulation such as a rotatable pod shelf and a pod transfer structure capable of transferring a FOUP (Front Opening Unified Pod). For example, the virtual container transfer structure 406A retains a function of simulating a function of a container transfer structure 206A (see FIG. 5) described later.

The virtual substrate transfer structure 406B is constituted by components in the simulation such as a notch alignment device and a wafer transfer structure capable of loading and unloading a wafer (substrate) onto and out of a boat (substrate retainer). For example, the virtual substrate transfer structure 406B retains a function of simulating a function of a substrate transfer structure 206B (see FIG. 5) described later.

The virtual support transfer structure 406C is constituted by components in the simulation such as a boat elevator capable of transferring the boat and an arm connected to an elevating platform of the boat elevator. For example, the virtual support transfer structure 406C retains a function of simulating a function of a support transfer structure 206C (see FIG. 5) described later.

In addition, the virtual transfer controller 406 may also be connected to the container transfer structure 206A, the substrate transfer structure 206B and the support transfer structure 206C, which serve as transfer structures described later. The container transfer structure 206A, the substrate transfer structure 206B and the support transfer structure 206C may be collectively or individually referred to as the “real measuring structure”.

For example, the real measuring structure or the virtual measuring structure may include a component such as a manual controller (pendant) capable of controlling a teaching process (which is one of initial settings of the apparatus) and an I/O reader capable of loading a control program and the like from an external recording medium.

In the present specification, the measuring structure connected to the simulator 300 of the present embodiments can be selected from the real measuring structure or the virtual measuring structure. Thus, for example, when the real measuring structure is connected, it is possible to check the operation of the real measuring structure. Therefore, according to the simulator 300 of present embodiments, when replacing the measuring structure, it is possible to check an operation of the measuring structure that will replace the existing one by using the simulator 300 before actually installing the measuring structure to the substrate processing apparatus 1. Thereby, it is possible to contribute to reducing an exclusively occupied time of the substrate processing apparatus 1 (which is a time duration during which the substrate processing apparatus 1 is used exclusively for the checking) and the time to check the operation. In addition, the measuring structure connected to the simulator 300 of the present embodiments can be selected from the real measuring structure or the virtual measuring structure by setting the connection destination information of the measuring structure in the apparatus parameters. Therefore, according to the simulator 300 of the present embodiments, it is possible to directly use the apparatus parameters built into the substrate processing apparatus 1 as they are, and it is also possible to reduce the time to prepare parameters dedicated to the simulator 300. In addition, the measuring structures connected to the simulator 300 of the present embodiments may be a mixture of the real measuring structure and the virtual measuring structure.

In addition, the virtual measuring structure connected to the simulator 300 of the present embodiments notifies the virtual measuring structure controller of measurement data at a specific period, similar to the real measuring structure. In such a case, the virtual measuring structure performs the notification at a period in accordance with the execution speed. The virtual measuring structure controller notifies the simulator controller 301 of the measurement data received from each measuring structure, and the simulator controller 301 stores the measurement data in the simulator memory 304 and further notifies the display manipulator 307 of the measurement data. Therefore, according to the simulator 300 of the present embodiments, by setting the configuration of the simulator 300 (for example, the virtual process controller 405 and the virtual transfer controller 406) to be the same (substantially the same) as that of the apparatus (for example, the process controller 205 and the transfer controller 206), it is possible to directly use the apparatus control program and the apparatus parameters installed in the apparatus as they are, and it is also possible to perform the operation without additionally preparing the control program and the apparatus parameters for the simulator 300.

In addition, the virtual measuring structure controller includes the virtual process controller 405 and the virtual transfer controller 406. Further, the virtual process controller 405 connects to the measuring structures in a virtual substrate process system (virtual process system) or a real substrate process system (real process system). Further, the virtual transfer controller 406 connects to the measuring structures in a virtual substrate transfer system (virtual transfer system) or a real substrate transfer system (real transfer system) The virtual process controller 405 and the virtual transfer controller 406 acquire respective connection destinations from the apparatus parameters, connect to the real measuring structures or the virtual measuring structures, and acquire the measurement data from the measuring structures connected thereto. Therefore, according to the simulator 300 of the present embodiments, it is possible to connect to the measuring structures defined by the apparatus parameters using the virtual process controller 405 and the virtual transfer controller 406, and it is also possible to perform the simulation. It is also possible to directly use the apparatus control program and the apparatus parameters installed in the substrate processing apparatus 1 as they are. In addition, the worker can perform the simulation without being aware of whether the measuring structure is the real measuring structure or the virtual measuring structure.

### Substrate Processing Apparatus

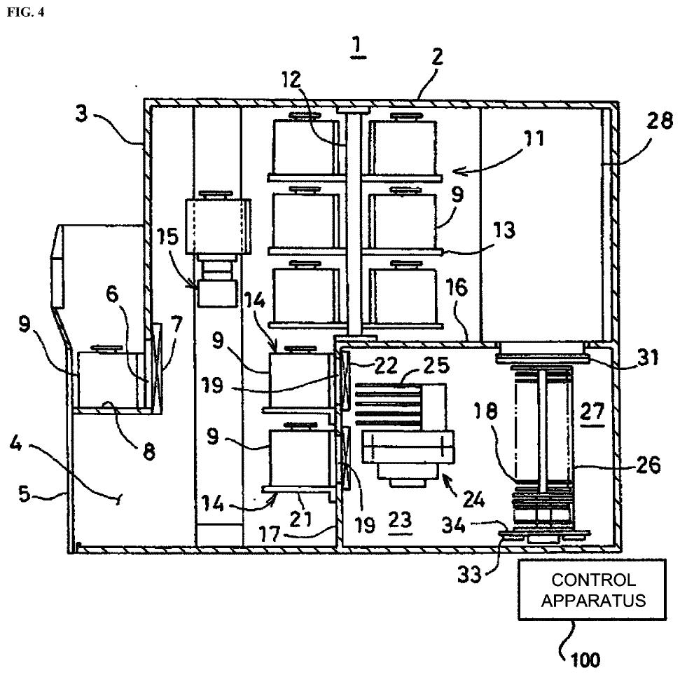

Subsequently, an overview of the substrate processing apparatus 1 according to the present embodiments will be described with reference to FIGS. 3 and 4. The substrate processing apparatus 1 according to the present embodiments is an example of the apparatus simulated by the simulator 300.

FIG. 3 is a diagram schematically illustrating an exemplary perspective view of the substrate processing apparatus 1 according to the present embodiments, and FIG. 4 is a diagram schematically illustrating a cross-section of the substrate processing apparatus 1 according to the present embodiments, when viewed from side thereof. In FIGS. 3 and 4, as an example of the substrate processing apparatus 1, a vertical type substrate processing apparatus is shown. For example, as an example of the substrate processed in the substrate processing apparatus 1, a semiconductor wafer made of a material such as silicon may be used.

As shown in FIGS. 3 and 4, the substrate processing apparatus 1 includes a housing 2. A front maintenance port 4 serving as an opening provided for maintenance is provided at a lower portion of a front wall 3 of the housing 2. The front maintenance port 4 may be opened or closed by a front maintenance door 5.

A pod loading/unloading port 6 is provided at the front wall 3 of the housing 2 so as to communicate between an inside and an outside of the housing 2. The pod loading/unloading port 6 may be opened or closed by a front shutter (which is a pod loading/unloading port opening/closing structure) 7. A loading port structure (which is a loading port shelf, that is, a transfer table for a substrate transfer container) 8 is provided in front of the pod loading/unloading port 6. The loading port structure 8 is configured such that a pod 9 is aligned while placed on the loading port structure 8.

For example, the pod 9 is configured as a sealed type substrate transfer container. The pod 9 may be transferred (loaded) into and placed on the loading port structure 8 by an in-process transfer apparatus (not shown) and may be transferred (unloaded) out of the loading port structure 8 by the in-process transfer apparatus.

A rotatable pod shelf (which is a storage shelf for the substrate transfer container) 11 is provided in the housing 2 to be located over a substantially center portion of the housing 2 in a front-rear direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”.

The rotatable pod shelf 11 includes: a vertical support column 12 capable of rotating intermittently; and a plurality of shelf plates (which are placement shelves for the substrate transfer container) 13. The plurality of shelf plates 13 are configured to be supported (or fixed) radially by the vertical support column 12 at positions of an upper portion, a mid portion and a lower portion of the vertical support column 12. Each of the plurality of shelf plates 13 is configured to accommodate at least one of the pods 9.

A pod opener (which is a structure capable of opening and closing a lid of the substrate transfer container) 14 is provided below the rotatable pod shelf 11. The pod opener 14 is provided with a configuration on which the pod 9 is placed and capable of opening and closing a lid of the pod 9.

A pod transfer structure (which is a container transfer structure) 15 is provided among the loading port structure 8, the rotatable pod shelf 11 and the pod opener 14. The pod transfer structure 15 is configured such that the pod 9 can be elevated and lowered and can be moved forward and backward in a horizontal direction while being supported by the pod transfer structure 15. The pod transfer structure 15 is further configured such that the pod 9 can be transferred among the loading port structure 8, the rotatable pod shelf 11 and the pod opener 14.

A sub-housing 16 is provided below the substantially center portion of the housing 2 in the front-rear direction to extend toward a rear end of the substrate processing apparatus 1. A pair of wafer loading/unloading ports (substrate loading/unloading ports) 19 through which the wafer 18 serving as the substrate is loaded into or unloaded out of the sub-housing 16 is provided at a front wall 17 of the sub-housing 16. The pair of wafer loading/unloading ports 19 is arranged vertically in two stages. A pair of pod openers (including the pod opener 14) is provided at the pair of wafer loading/unloading ports 19, respectively. For example, an upper pod opener and a lower pod opener may be provided as the pair of pod openers. The upper pod opener and the lower pod opener may be collectively or individually referred to as the “pod opener 14”.

The pod opener 14 may include: a placement table 21 where the pod 9 is placed thereon; and an attaching/detaching structure 22 capable of attaching and detaching the lid of the pod 9. The pod opener 14 is configured such that a wafer entrance of the pod 9 is opened or closed by detaching or attaching the lid of the pod 9 placed on the placement table 21 by the attaching/detaching structure 22.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure (which is a substrate transfer structure) 24 is provided at a front region of the transfer chamber 23. The wafer transfer structure 24 may include a predetermined number of wafer placement plates (for example, as shown in FIG. 4, five wafer placement plates) 25 on which a predetermined number of wafers including the wafer 18 are placed. The wafer placement plates 25 can be moved linearly in the horizontal direction, can be rotated in the horizontal direction and can be elevated or lowered in a vertical direction. The wafer transfer structure 24 is configured such that the wafer 18 can be loaded into or unloaded out of the boat (which is the substrate retainer) 26.

In a rear region of the transfer chamber 23, a standby space 27 where the boat 26 is accommodated and in standby is provided, and a process furnace 28 such as a vertical type process furnace is provided above the standby space 27. A process chamber 29 is provided inside the process furnace 28, and a lower end portion of the process chamber 29 is configured as a furnace opening. The furnace opening is opened or closed by a furnace opening shutter (which is a furnace opening opening/closing structure) 31. The process chamber 29 may also be referred to as a “process vessel” which is an example of a processing structure.

A boat elevator (which is a substrate retainer elevating structure) 32 capable of elevating and lowering the boat 26 is provided between a right end of the housing 2 and a right end of the standby space 27 of the sub-housing 16. A seal cap 34 serving as a lid is horizontally attached to the arm 33 connected to the elevating platform of the boat elevator 32. The seal cap 34 is configured such that the boat 26 can be vertically supported by the seal cap 34, and such that the furnace opening can be airtightly closed by the seal cap 34 while the boat 26 is loaded into the process chamber 29.

The boat 26 is configured such that a plurality of wafers (for example, from 50 wafers to 200 wafers) including the wafer 18 are supported on the boat 26 in a horizontal orientation in a multistage manner with their centers aligned with one another. Hereinafter, the plurality of wafers including the wafer 18 may also be simply referred to as “wafers 18”. In addition, in the present specification, a notation of a numerical range such as “from 50 wafers to 200 wafers” means that a lower limit and an upper limit are contained in the numerical range. Therefore, for example, a numerical range “from 50 wafers to 200 wafers” means a range equal to or higher than 50 wafers and equal to or less than 200 wafers. The same also applies to other numerical ranges described in the present specification.

A clean air supplier (which is a clean air supply structure or a clean air supply system) 35 is arranged at a position facing the boat elevator 32. The clean air supplier 35 is constituted by a supply fan and a dustproof filter so as to supply clean air 36 such as an inert gas and a clean atmosphere. As the inert gas, for example, a nitrogen (N)-containing gas may be used. As the nitrogen-containing gas, for example, a gas such as nitrogen (N₂) gas and ammonia (NH₃) gas may be used. As the nitrogen-containing gas, for example, one or more of the gases exemplified above may be used. A notch alignment device (not shown) serving as a substrate alignment device configured to align a circumferential position of the wafer 18 is provided between the wafer transfer structure 24 and the clean air supplier 35.

The clean air 36 ejected from the clean air supplier 35 is circulated in components such as the notch alignment device (not shown), the wafer transfer structure 24 and the boat 26. Thereafter, the clean air 36 is exhausted out of the housing 2 through a duct (not shown), or is ejected again into the transfer chamber 23 by the clean air supplier 35.

Subsequently, an operation of the substrate processing apparatus 1 will be described.

When the pod 9 is supplied to the loading port structure 8, the pod loading/unloading port 6 is opened by the front shutter 7. Then, the pod 9 placed on the loading port structure 8 is transferred (loaded) into the housing 2 through the pod loading/unloading port 6 by the pod transfer structure 15, and is placed on a designated shelf plate among the plurality of shelf plates 13 of the rotatable pod shelf 11. The pod 9 is temporarily stored on the rotatable pod shelf 11. Then, the pod 9 is transferred from the designated shelf plate among the plurality of shelf plates 13 to the placement table 21 of the pod opener 14 (that is, one of the upper pod opener and the lower pod opener) by the pod transfer structure 15. Alternatively, the pod 9 may be transferred directly from the loading port structure 8 to the placement table 21 of the pod opener 14.

When the pod 9 is being transferred, the wafer loading/unloading ports 19 are closed by the attaching/detaching structure 22, and the transfer chamber 23 is filled with the clean air 36. For example, the transfer chamber 23 is filled with the nitrogen-containing gas serving as the clean air 36 such that an oxygen concentration in the transfer chamber 23 is set to 20 ppm or less, for example, which is lower than an oxygen concentration in the housing 2 (which is under an atmospheric atmosphere).

When an end surface of the pod 9 placed on the placement table 21 is pressed against an opening edge of one of the pair of wafer loading/unloading ports 19 of the front wall 17 of the sub-housing 16, the attaching/detaching structure 22 detaches the lid of the pod 9 and the wafer entrance of the pod 9 is opened.

When the pod 9 is opened by the pod opener 14 (that is, one of the upper pod opener and the lower pod opener), the wafer 18 is then taken out from the pod 9 by the wafer transfer structure 24, transferred to the notch alignment device (not shown), and aligned by the notch alignment device. Then, by the wafer transfer structure 24, the wafer 18 is transferred (or loaded) into the standby space 27 provided in the rear region of the transfer chamber 23, and loaded (or charged) into the boat 26.

After the wafer 18 is charged into the boat 26, the wafer transfer structure 24 then returns to the pod 9 and transfers a next wafer among the wafers 18 from the pod 9 into the boat 26.

While the wafer transfer structure 24 loads the wafers 18 into the boat 26 through the pod opener 14 (which is one of the upper pod opener and the lower pod opener), another pod 9 is transferred from the rotatable pod shelf 11 by the pod transfer structure 15 to the pod opener 14 (which is the other one of the upper pod opener and the lower pod opener), and the lid of the aforementioned another pod 9 is opened by the other one of the upper pod opener and the lower pod opener.

When a predetermined number of wafers including the wafer 18 are charged into the boat 26, the furnace opening of the process furnace 28 closed by the furnace opening shutter 31 is opened by the furnace opening shutter 31. Subsequently, the boat 26 accommodating the wafers 18 is elevated by the boat elevator 32 such that the boat 26 is loaded (inserted) into the process chamber 29.

After the boat 26 is loaded, the furnace opening is airtightly closed by the seal cap 34. In addition, according to the present embodiments, at such a timing (that is, after the boat 26 is loaded), a purge step (also referred to as a “pre-purge step”) of replacing an atmosphere (inner atmosphere) of the process chamber 29 with the inert gas is performed.

The process chamber 29 is vacuum-exhausted by a gas exhaust structure (which is a gas exhauster) (not shown) such that a pressure (inner pressure) of the process chamber 29 reaches and is maintained at a desired pressure (vacuum degree). In addition, the process chamber 29 is heated to a predetermined temperature by a heater driver (not shown) such that a desired temperature distribution of the process chamber 29 is obtained.

In addition, a process gas whose flow rate is controlled to a predetermined flow rate is supplied by a gas supply structure (which is a gas supplier) (not shown), and the process gas comes into contact with a surface of the wafer 18 while flowing through the process chamber 29. Thereby, a predetermined processing such as a substrate processing described later is performed on the surface of the wafer 18. In addition, the process gas after a reaction in the predetermined processing is exhausted from the process chamber 29 by the gas exhaust structure. In the present specification, the term “process gas” refers to a gas supplied into the process chamber 29. The same also applies to the following description.

After a predetermined process time has elapsed, the inert gas is supplied from an inert gas supply source (not shown) by the gas supply structure, the inner atmosphere of the process chamber 29 is replaced with the inert gas, and the inner pressure of the process chamber 29 is returned to the normal pressure (after-purge step). Then, the boat 26 is lowered by the boat elevator 32 through the seal cap 34. In the present specification, the term “process time” refers to a time duration of continuously performing a process related thereto. The same also applies to the following description.

After the wafer 18 is processed, the wafer 18 and the pod 9 are transferred (unloaded) out of the housing 2 in an order reverse to that of loading the wafer 18 and the pod 9 into the housing 2 described above. Then, an unprocessed wafer 18 is further loaded into the boat 26, and a batch processing for the wafer 18 is repeatedly performed.

According to the present embodiments, as shown in FIGS. 3 and 4, the substrate processing apparatus 1 includes the control apparatus (which is a control structure) 100, and the control apparatus 100 is configured to control the substrate processing apparatus 1. The control apparatus 100 may be provided (embedded) in the substrate processing apparatus 1, or may be provided outside the substrate processing apparatus 1 in a manner accessible thereto.

### Control Apparatus

Subsequently, with reference to FIG. 5, a configuration of a control system of the substrate processing apparatus 1 according to the present embodiments will be described. FIG. 5 is a block diagram schematically illustrating an example of a functional configuration of the control apparatus 100 provided for the substrate processing apparatus 1 according to the present embodiments.

As shown in FIG. 5, the substrate processing apparatus 1 includes the control apparatus (which is a main controller) 100, an external communication interface 201, an external memory 202, a manipulator 203, a display (which is a display structure) 204, an input device 207, the process controller 205 and the transfer controller 206.

For example, the control apparatus 100 includes a controller 101, a memory 104 and the I/O port 105. The controller 101 includes a CPU 102 and a RAM 103. While the manipulator 203 is illustrated separately from the controller 101, the manipulator 203 may be configured as a function of the controller 101.

The control apparatus 100 is connected to the manipulator 203, and further connected to the process controller 205 and the transfer controller 206 via the I/O port 105. Since the control apparatus 100 is electrically connected to each of the process controller 205 and the transfer controller 206 via the I/O port 105, each piece of data can be transmitted or received and each file can be downloaded or uploaded between the control apparatus 100 and each of the process controller 205 and the transfer controller 206.

The control apparatus 100 is connected to an external host computer (not shown) via the external communication interface 201. Therefore, even when the substrate processing apparatus 1 is installed in a clean room, the host computer can be disposed at a location such as an office outside the clean room. In addition, the external memory 202 (which serves as a mounting structure on which a recording medium such as the USB (Universal Serial Bus) memory is installed or removed) is connected to the control apparatus 100. For example, according to the present embodiments, the substrate processing apparatus 1 can deploy (or load) a recipe whose operation has been confirmed (checked) by the simulator 300 into the substrate processing apparatus 1 via the external memory 202, and can process the substrate using the recipe loaded in the substrate processing apparatus 1. According to the substrate processing apparatus 1 of the present embodiments, by using the recipe whose operation has been confirmed by the simulator 300 in the apparatus, it is possible to reduce a loss (such as a loss in the substrates and a loss in an energy) due to an execution of an erroneous recipe.

For example, the manipulator 203 serving as a manipulation controller may include the display 204 and the input device 207 which are configured as an integrated structure (that is, integrated into a single structure), or may be connected to the display 204 via a connector such as a video cable and to the input device 207 via a connector such as a signal cable. For example, the display 204 is configured as a liquid crystal display panel. For example, the input device 207 is configured as an input structure such as a keyboard and a mouse. Alternatively, the manipulator 203, the display 204 and the input device 207 may be configured as an integrated structure as a touch panel. Various operation screens for operating the substrate processing apparatus 1 can be displayed on the display 204. For example, each operation screen may include a screen through which a state of a substrate processing system controlled by the process controller 205 and a state of a substrate transfer system controlled by the transfer controller 206 can be checked. In such a case, the display 204 can display various operation buttons serving as an input interface (input structure) through which an operation instruction can be input to the substrate processing system and the substrate transfer system, or can display various input fields. Each operation button can be selected or pressed via the manipulator 203 based on an instruction input from the input device 207. In addition, for example, a numerical value can be input to each input field via the manipulator 203 based on the instruction input from the input device 207. The manipulator 203 displays information generated in the substrate processing apparatus 1 on the display 204 via the operation screen. For example, the manipulator 203 outputs the information input from the input device 207 or the information displayed on the display 204 to a structure (device) such as the USB memory inserted in the external memory 202. The manipulator 203 accepts (or receives) input data (input instruction) input from a user via the operation screen displayed on the display 204 and transmits the input data to the control apparatus 100. In addition, the manipulator 203 is configured to receive, via the input device 207, an instruction (control instruction) to execute an appropriate substrate processing recipe (also referred to as a “process recipe”) among recipes deployed in the RAM 103 or recipes stored in the memory 104, and is further configured to transmit the instruction to the control apparatus 100. For example, the manipulator 203 and the display 204 are provided separately from the control apparatus 100. However, the manipulator 203, the display 204 and the control apparatus 100 may be configured as an integrated structure.

In the processing chamber 29, the substrate is processed in accordance with the recipe including at least one step defining the process conditions for the substrate. In other words, the recipe is constituted by one or more steps.

The manipulator 203 accepts an editing operation (such as an operation of adding a new step into the recipe, an operation of deleting an existing step in the recipe, an operation of changing an order of the steps included in the recipe, and an operation of setting repeated executions of the recipe) from the user (that is, the worker) via the input device 207. In addition, the manipulator 203 accepts an editing operation for at least one setting item included in the process conditions of a selected step among the steps in the recipe. In other words, the manipulator 203 accepts, from the user, the editing operation for the steps included in the recipe and the editing operation for at least one setting item included in the process conditions of each step via the operation screen.

The process controller 205 includes the temperature measuring structure 205A, the gas flow rate measuring structure 205B and the pressure measuring structure 205C. Each of the temperature measuring structure 205A, the gas flow rate measuring structure 205B and the pressure measuring structure 205C constitutes a sub-controller, and is electrically connected to the process controller 205. Thereby, each piece of data can be transmitted or received and each file can be downloaded or uploaded between the process controller 205 and each sub-controller (that is, the temperature measuring structure 205A, the gas flow rate measuring structure 205B and the pressure measuring structure 205C). For example, the process controller 205 and each sub-controller are configured as a separate structure. However, the process controller 205 and each sub-controller may be configured as an integrated structure.

The heating structure constituted mainly by the heater and the temperature sensor (mot shown) is connected to the temperature measuring structure 205A. For example, the temperature measuring structure 205A is configured to adjust the temperature (inner temperature) of the process furnace 28 by controlling the temperature of the heater of the process furnace 28. In addition, the temperature measuring structure 205A is configured to control a switching operation (turn on/turn off operation) of a thyristor and to control an electrical power supplied to a heater wire of the heater.

The gas flow rate measuring structure 205B is connected to the MFC (Mass Flow Controller) (not shown) which is provided on a gas piping configured to supply a predetermined gas into the process chamber 29. The MFC serves as a gas flow controller configured to control a flow rate of the gas being supplied. When an opening/closing valve (also simply referred to as a “valve”), in addition to the MFC, is provided on the gas piping, the gas flow rate measuring structure 205B may be configured to control the opening/closing valve together with the MFC. The gas flow rate measuring structure 205B is configured to control a valve opening degree of the MFC such that the flow rate of the gas supplied into the process chamber 29 reaches and is maintained at a specified value. In addition, the MFC may be configured as the gas flow rate measuring structure 205B and directly connected to the process controller 205.

The gas exhaust structure (not shown) constituted mainly by the pressure sensor (not shown) and the APC (automatic pressure control) valve (not shown) serving as a pressure valve is connected to the pressure measuring structure 205C. In addition, the gas exhaust structure may further include a vacuum pump (not shown). The pressure measuring structure 205C is configured to control an opening degree of the APC valve and a switching operation (turn on/turn off operation) of the vacuum pump such that the inner pressure of the process chamber 29 reaches and is maintained at a specified pressure at a specified timing based on a pressure value detected by the pressure sensor.

The transfer controller 206 is provided with: the container transfer structure 206A configured to transfer a container capable of storing the substrates in a multistage manner; the substrate transfer structure 206B configured to transfer the substrate; and the support transfer structure 206C configured to transfer a support (support structure) capable of supporting the substrates. The container transfer structure 206A, the substrate transfer structure 206B and the support transfer structure 206C are configured to control each of a drive system, a rotation system and an elevating system of the substrate processing apparatus 1. For example, the transfer controller 206 is configured to respectively control transfer operations of the rotatable pod shelf 11, the boat elevator 32, the pod transfer structure 15, the wafer transfer structure 24, the boat 26 and a rotator (not shown).

The container transfer structure 206A is configured to transfer the pod 9 by controlling components such as the rotatable pod shelf 11 and the pod transfer structure 15. The substrate transfer structure 206B is configured to load the wafer 18 into the boat 26 and unload the wafer 18 out of the boat 26 by controlling components such as the wafer transfer structure 24 and the notch alignment device. The support transfer structure 206C is configured to transfer the boat 26 by controlling components such as the boat elevator 32 and the arm 33.

For example, according to the present embodiments, each of the control apparatus 100, the process controller 205 and the transfer controller 206 may be embodied by a general computer system instead of a dedicated computer system. For example, by installing in the general computer system a program for executing the predetermined processing described above from a predetermined recording medium (such as a CD-ROM and a USB memory) storing the program, each controller described above may be provided to perform the predetermined processing.

In addition, a method of supplying the program can be appropriately selected. Instead of or in addition to being supplied through the predetermined recording medium as mentioned above, for example, the program may be provided through a communication line, a communication network or a communication system.

For example, the control apparatus 100 is configured as a computer including the CPU 102, the RAM 103, the memory 104 and the I/O port 105. In the memory 104, a recipe file such as the recipe 104B in which process conditions and process procedures of the substrate processing are defined, the apparatus control program 104A for executing each recipe file, the apparatus parameters 104C (setting parameter file) for setting the process conditions and the process procedures, and apparatus data (“AD” in FIG. 5) 104D serving as the measurement data acquired from each measuring structure may be stored. For example, the control apparatus 100 is electrically connected to the network such as the Internet, the LAN (Local Area Network) and the WAN (Wide Area Network) by using the external communication interface 201, and is configured to be capable of communicating with external apparatuses via the network. For example, the apparatus control program 104A may be installed in advance in the substrate processing apparatus 1. Alternatively, the apparatus control program 104A may be embodied by recording a program related thereto on a non-volatile recording medium (or distributing the program related thereto via the network) and installing the program related thereto appropriately in the substrate processing apparatus 1. For example, as the non-volatile recording medium, a component such as a CD-ROM, a magneto-optical disk, a hard disk drive (HDD), a DVD-ROM, a flash memory, a memory card and a USB memory may be used.

For example, as the memory 104, a component such as a hard disk drive (HDD), a solid state drive (SSD) and a flash memory may be used.

### Start-Up Screen

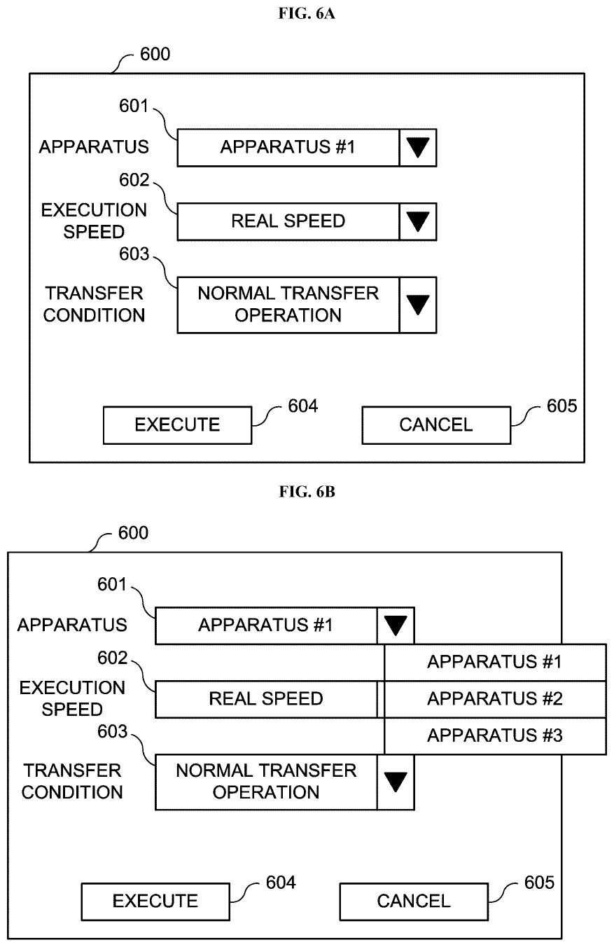

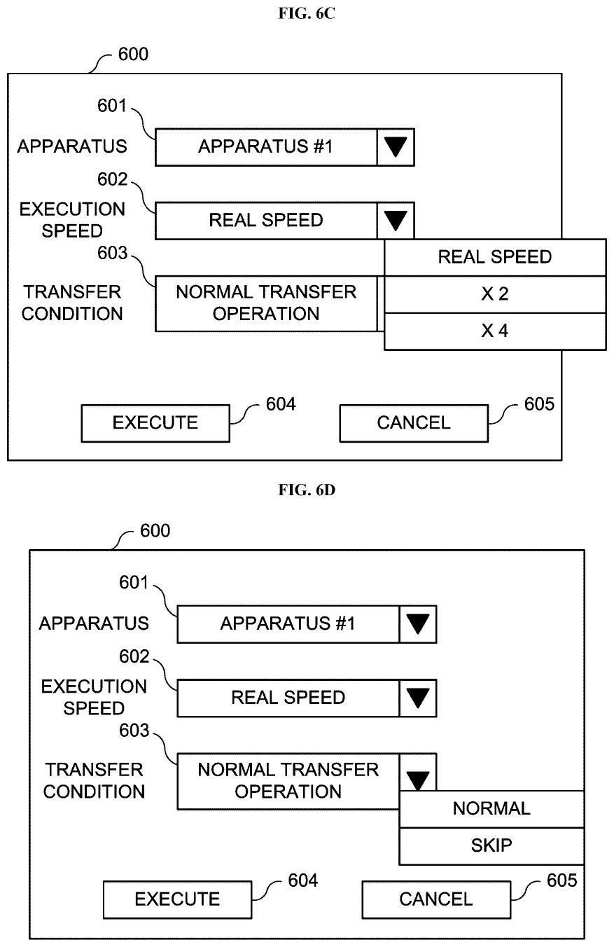

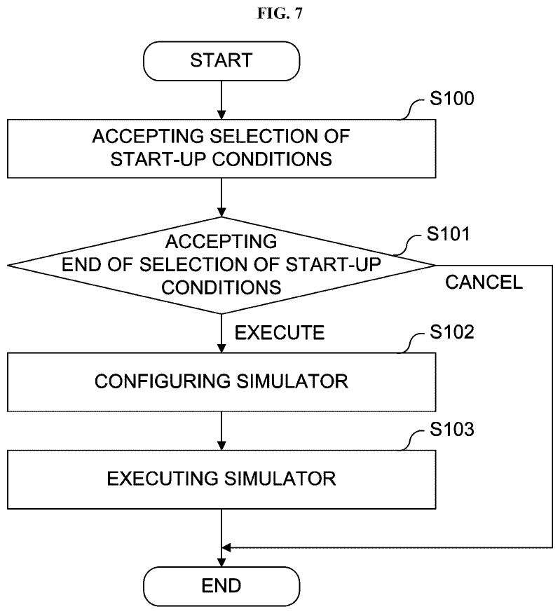

Subsequently, with reference to FIGS. 6A to 6D, examples of screen transitions on the display manipulator 307 associated with the start-up process of the simulator 300 according to the present embodiments will be described.

When the start-up process to be described below is executed in the simulator 300, the CPU 302 displays a start-up screen 600 on the display manipulator 307 as shown in FIG. 6A. The start-up screen 600 is a screen for selecting the environmental settings for the start-up environment of the simulator 300. According to the present embodiments, the start-up screen 600 may include: an apparatus list 601 from which the apparatus can be selected; an execution speed list 602 from which the execution speed can be selected; a transfer condition list 603 from which a transfer condition for the transfer operation can be selected; an execution button 604; and a cancel button 605. For example, according to the present embodiments, the display manipulator 307 is a touch panel, and is configured to be capable of allowing for a touch operation by the worker. In addition, the start-up screen 600 displayed on the display manipulator 307 may be displayed in an entirety of a display area of the display manipulator 307, or may be displayed in a part of the display area (for example, an area such as a dialog window).

In the present embodiments, for example, the apparatus list 601 is configured such that the apparatus #1, the apparatus #2 and the apparatus #3 can be selected. Therefore, when the worker presses the apparatus list 601, a screen shown in FIG. 6B is displayed. As shown in FIG. 6B, the start-up screen 600 displays options “APPARATUS #1”, “APPARATUS #2” and “APPARATUS #3” in a pull-down list (drop-down list) such that the worker can select a desired apparatus.

The execution speed list 602 shown in FIG. 6A is configured such that the real speed, the double speed and the quadruple speed can be selected. Therefore, when the worker presses the execution speed list 602, a screen shown in FIG. 6C is displayed. As shown in FIG. 6C, the start-up screen 600 displays options “REAL SPEED”, “X2” indicating the double speed and “X4” indicating the quadruple speed in a pull-down list such that the worker can select a desired execution speed.

The transfer condition list 603 shown in FIG. 6A is configured such that the normal transfer operation and the transfer skip operation can be selected. Therefore, when the worker presses the transfer condition list 603, a screen shown in FIG. 6D is displayed. As shown in FIG. 6D, the start-up screen 600 displays options “NORMAL” indicating the normal transfer operation and “SKIP” indicating the transfer skip operation in a pull-down list such that the worker can select a desired transfer condition. For example, when the measuring structure connected to the simulator 300 is the real measuring structure, the transfer condition list 603 may be hidden, or may be inactivated so that it does not respond even when pressed.

The execution button 604 in FIG. 6A is a button for executing the simulation of the apparatus (which is selected from the apparatus list 601) at the execution speed (which is selected from the execution speed list 602) and under the transfer condition (which is selected from the transfer condition list 603). In addition, the cancel button 605 is a button for canceling the execution of the simulation.

That is, the display manipulator 307 displays a selection screen for an apparatus selection, an execution speed selection and a transfer operation mode selection when the simulator 300 is started, and prompts the worker to select each selection item. When the execution button 604 is pressed, the display manipulator 307 notifies the simulator controller 301 of the information which is selected. The simulator controller 301 instructs the operating environment setting structure 402 to deploy the operating environment of the apparatus which is selected, notifies the time monitoring structure 403 of the execution speed which is selected, and notifies the virtual transfer controller 406 of the transfer condition which is selected. Then, the apparatus control program of the apparatus (which is selected) is started to start the simulation of the apparatus which is selected. When starting the simulation, the simulator 300 of the present embodiments operates in accordance with items selected from apparatus selection items, execution speed selection items and transfer condition selection items displayed on the screen of the display manipulator 307. According to the simulator 300 of the present embodiments, it is possible to reduce a time taken for the worker to perform a setting operation. In addition, the simulator controller 301 starts the apparatus control program using start-up conditions from the start-up operator 401. Since the apparatus control program is same (substantially the same) as the program stored in each apparatus, the display manipulator 307 of the simulator 300 can also simulate the operation of each apparatus.

### Flow Chart

FIG. 7 is a flow chart schematically illustrating an example of the start-up process according to the present embodiments. For example, the start-up process shown in FIG. 7 is executed when the simulator 300 is started.

In a step S100 in FIG. 7, the CPU 302 accepts a selection of the start-up conditions. Specifically, the CPU 302 displays the apparatus list 601, the execution speed list 602 and the transfer condition list 603 (see FIG. 6A), and accepts each selection of the apparatus, the execution speed and the transfer condition.

In a step S101, the CPU 302 is notified of an end of the selection of the start-up conditions. When the CPU 302 accepts pressing of the execution button 604 (step S101: “EXECUTE”), a step S102 is performed. On the other hand, when the CPU 302 accepts pressing of the cancel button 605 (step S101: “CANCEL”), the start-up process is terminated.

In the step S102, the CPU 302 configures the simulator 300. Specifically, the CPU 302 sets the operating environment of the apparatus selected in the step S100 (that is, reproduces the operating environment of the real apparatus). For example, the CPU 302 creates a folder structure and deploys various files.

In a step S103, the CPU 302 executes the simulator 300. Specifically, the CPU 302 executes the apparatus control program for the apparatus selected in the step S100 at the execution speed and under the transfer condition selected in the step S100. Then, the CPU 302 terminates the start-up process.

According to the simulator 300 of the present embodiments, the apparatus control program (which is installed in the substrate processing apparatus 1) and the apparatus parameters (which define setting information related to the configuration of the apparatus and the process conditions of the substrate) can be stored in the simulator memory 304. The recipe (in which the process conditions of the substrate are set) can also be stored in the simulator memory 304. For example, the recipe is constituted by a plurality of steps for each substrate processing operation, and the process time is defined for each of the steps. When starting the apparatus control program, the simulator controller 301 executes the apparatus control program in accordance with the execution speed and the transfer operation mode selected by the start-up operator 401.

According to the simulator 300 of the present embodiments, it is possible to obtain one or more of the following effects.

By simulating the substrate processing operation in accordance with the recipe which is edited and without actually using the substrate processing apparatus 1, it is possible to reduce a time for editing the recipe.

By using the apparatus control program and the apparatus parameters installed in the substrate processing apparatus 1, it is possible for the simulator 300 to perform the same (substantially the same) operation as the substrate processing apparatus 1.

By executing the apparatus control program in accordance with the execution speed and the transfer operation mode selected as described above, it is possible to adjust the time to check the substrate processing operation, and it is also possible to check the operation of the recipe (which is executed) in a short time.

For example, when using the real apparatus, it takes time to assemble and install the substrate processing apparatus 1, and the operation can only be checked after the installation of the substrate processing apparatus 1 is completed. However, when using the simulator 300, it is possible to check the operation even without actually using the substrate processing apparatus 1.

In addition, when the transfer skip operation is selected, it is possible to skip the operation of the transfer system. Thereby, it is possible to check the substrate processing operation in a shorter time.

### Other Embodiments of Present Disclosure

For example, the simulator 300 and the substrate processing apparatus 1 according to the embodiments mentioned above are described above as an example. However, the technique of the present disclosure may also be applied to a program that causes a computer to perform the functions of the simulator 300 or the substrate processing apparatus 1. In addition, the technique of the present disclosure may also be applied to a non-transitory computer-readable recording medium storing the program that causes the computer to perform the functions of the simulator 300 or the substrate processing apparatus 1.

The configurations of the simulator 300 and the substrate processing apparatus 1 described in the embodiments mentioned above are merely examples, and may be modified in accordance with circumstances without departing from the scope of the technique of the present disclosure.

In addition, the process flow of the program described in the embodiments mentioned above is merely an example, and an unnecessary step may be deleted, a new step may be added or the process procedures may be changed, without departing from the scope of the technique of the present disclosure.

For example, the embodiments mentioned above are described by way of an example in which the processing according to the embodiments is implemented by a software configuration that uses the computer to execute the program. However, the technique of the present disclosure is not limited thereto. For example, the technique of the present disclosure may also be applied to a hardware configuration capable of performing the processing, or may also be applied to a combination of hardware and software configurations capable of performing the processing.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at a time is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

As described above, according to some embodiments of the present disclosure, it is possible to reduce the time for editing the recipe by simulating the processing operation for the substrate based on an edited recipe without using a substrate processing apparatus.

What is claimed is:

1. A simulator apparatus comprising:
a virtual apparatus memory configured to store a recipe and an apparatus control program, wherein the recipe is constituted by a plurality of steps defining process conditions and a process time for a substrate, and the apparatus control program is configured to control a processing of the substrate performed by a substrate processing apparatus using the recipe;
a start-up operator configured to select an execution speed of the apparatus control program and a transfer operation mode of a transfer structure transferring the substrate, wherein the transfer operation mode is selected from a normal transfer operation and a transfer skip operation;
a virtual controller configured to be capable of starting the apparatus control program based on the execution speed and the transfer operation mode of the transfer structure, and capable of controlling a virtual processing of the substrate based on the recipe stored in the virtual apparatus memory.

2. The simulator apparatus of claim 1, wherein the transfer structure comprises at least one among: a container transfer structure configured to transfer a container capable of storing the substrate and one or more substrates in a multistage manner; a substrate transfer structure configured to transfer the substrate; and a support transfer structure configured to transfer a support capable of supporting the substrate to a process vessel in which the substrate is processed.

3. The simulator apparatus of claim 1, further comprising
a time monitoring structure configured to control the execution speed of the apparatus control program,
wherein the start-up operator is further configured to select the execution speed from a plurality of execution speeds comprising a real speed and an integral multiple of the real speed, and
wherein the time monitoring structure is further configured to monitor a time for the virtual processing in accordance with the execution speed selected by the start-up operator.

4. The simulator apparatus of claim 1, wherein the virtual apparatus memory is further configured to store a plurality of recipes of a plurality of substrate processing apparatuses and a plurality of apparatus control programs of the plurality of substrate processing apparatuses,
wherein the start-up operator is further configured to be capable of selecting the substrate processing apparatus from the plurality of substrate processing apparatuses.

5. The simulator apparatus of claim 4, further comprising
an operating environment setting structure configured to set an operating environment for the substrate processing apparatus selected by the start-up operator,
wherein the operating environment setting structure is further configured to acquire apparatus configuration information corresponding to the substrate processing apparatus from the virtual apparatus memory, to generate a folder based on the apparatus configuration information, and to set the operating environment in the folder, and
wherein the operating environment comprises at least one of the recipe or the apparatus control program of the substrate processing apparatus.

6. The simulator apparatus of claim 5, wherein the virtual apparatus memory is further configured to store apparatus parameters defining a configuration of a measuring structure comprising the transfer structure connected to the substrate processing apparatus, and
wherein the operating environment setting structure is further configured to acquire the apparatus parameters of the substrate processing apparatus selected by the start-up operator from the virtual apparatus memory, and to deploy the apparatus parameters in the folder generated by the operating environment setting structure.

7. The simulator apparatus of claim 6, wherein connection conditions for the measuring structure connected to the substrate processing apparatus are capable of being set in the apparatus parameters, and
wherein the virtual controller is further configured to be capable of connecting to the measuring structure set by the apparatus parameters by using the apparatus control program, and capable of controlling the virtual processing of the substrate by executing the recipe.

8. The simulator apparatus of claim 7, wherein the connection conditions for the measuring structure in the apparatus parameters are specified by setting connection destination information of the measuring structure defined in the apparatus parameters.

9. The simulator apparatus of claim 7, further comprising
a virtual measuring structure controller configured to be capable of connecting to the measuring structure defined in the apparatus parameters and capable of controlling communication with the measuring structure,
wherein the virtual measuring structure controller is further configured to notify the virtual controller of measurement data reported by the measuring structure.

10. The simulator apparatus of claim 9, wherein the virtual measuring structure controller comprises:
a virtual process controller connected to a process system measuring structure in the measuring structure; and
a virtual transfer controller connected to the transfer structure in the measuring structure.

11. The simulator apparatus of claim 10, wherein the virtual process controller is further configured to, when the virtual process controller is connected to the measuring structure, acquire data reported from a virtual measuring structure if the measuring structure is set as the virtual measuring structure in the apparatus parameters, and acquire data reported from a real measuring structure if the measuring structure is set as the real measuring structure in the apparatus parameters.

12. The simulator apparatus of claim 10, wherein, when the virtual transfer controller is connected to the transfer structure, the virtual transfer controller is further configured to acquire data reported from a virtual transfer structure if the transfer structure is set as the virtual transfer structure in the apparatus parameters, and to acquire data reported from a real transfer structure if the transfer structure is set as the real transfer structure in the apparatus parameters.

13. The simulator apparatus of claim 10, wherein, when the transfer structure connected to the virtual transfer controller is set as a real transfer structure in the apparatus parameters, a selection of the transfer skip operation as the transfer operation mode of the transfer structure is inactivated.

14. The simulator apparatus of claim 1, further comprising
a virtual apparatus display manipulator configured to display selection information for the execution speed and the transfer operation mode of the transfer structure,
wherein the virtual apparatus display manipulator is further configured to display selection items of the execution speed and selection items of the transfer operation mode of the transfer structure.

15. The simulator apparatus of claim 14, wherein the virtual apparatus display manipulator is further configured to notify the virtual controller when the execution speed is selected among the selection items of the execution speed and the transfer operation mode of the transfer structure is selected among the selection items of the transfer operation mode.

16. The simulator apparatus of claim 14, wherein the recipe is editable, and the recipe is edited using the virtual apparatus display manipulator.

17. A simulation method comprising
(a) storing a recipe and an apparatus control program, wherein the recipe is constituted by a plurality of steps defining process conditions and a process time for a substrate, and the apparatus control program is configured to control a processing of the substrate performed by a substrate processing apparatus using the recipe;
(b) selecting an execution speed of the apparatus control program and a transfer operation mode of a transfer structure transferring the substrate when starting a simulator apparatus, wherein the transfer operation mode is selected from a normal transfer operation and a transfer skip operation; and
(c) starting the apparatus control program based on the execution speed and the transfer operation mode of the transfer structure selected in (b), and controlling a virtual processing of the substrate based on the recipe stored in (a).

18. A substrate processing apparatus comprising:
a process chamber in which a substrate is processed,
wherein the substrate is processed by using the recipe stored in the simulator apparatus of claim 1.

19. A method of manufacturing a semiconductor device performed by the substrate processing apparatus of claim 18, comprising:
(a) transferring the substrate into the process chamber; and
(b) processing the substrate.

20. A non-transitory computer-readable recording medium storing a program that causes the substrate processing apparatus of claim 18, by a computer, to perform
(a) transferring the substrate into the process chamber; and
(b) processing the substrate.
